(19) United States
(12) Patent Application Publication
(10) Pub. No.: US 2006/0181266 A1
(43) Pub. Date: Aug. 17, 2006

(54) Flat panel display inspection system

(75) Inventor: Guillermo L. Toro-Lira, Sunnyvale, CA (US)

Correspondence Address: Robert E. Krebs;Thelen Reid & Priest LLP, P. O. Box 640640, San Jose, CA, 95164-0640, US

(73) Assignee: Panelvision Technology, a California Corporation

(21) Appl. No.: 11/058,437

(22) Filed: Feb. 14, 2005

(51) Int. Cl. G01R 31/28

(52) U.S. Cl. 324/158.1

(57) ABSTRACT

A substrate inspection system includes a plurality of load-lock-less inspection chambers, which are share a single pump unit. A plurality of valves are configured to selectively couple the pump unit to a selected one of the plurality of inspection chambers. The pump unit is configured to pump air out of the selected one of the plurality of inspection chambers while a substrate or substrates in one or more of the remaining plurality of load-lock-less inspection chambers is being inspected. Each load-lock-less inspection chamber may have an associated plurality of rows of electron guns. The plurality of rows of electron guns are operable to provide an electron source for performing voltage waveform contrasting. By employing load-lock-less inspection chambers, a single, shared pump unit, and/or the plurality of rows of electron guns, the footprint of the substrate inspection system can be minimized.

### FIELD OF THE INVENTION

The present invention relates to the inspection of flat panel displays.

### BACKGROUND OF THE INVENTION

Flat-panel displays (FPDs) are commonly employed as displays for laptop computers, and are increasingly displacing the conventional CRT-based monitor traditionally used for desktop computers and television sets.

FPDs may be manufactured from various types of display technologies. The most prevalent display technology is the liquid crystal display (LCD). The LCD consists of an electrically-controlled light-polarizing liquid that is disposed between two transparent polarizing sheets. The polarizing axes of the two polarizing sheets are aligned perpendicular to each other. Electrical contacts are also provided, which allow an electric field to be applied to the liquid crystal inside.

With no external electric field applied to the contacts, the long, thin molecules of the liquid crystal are in a relaxed state. Ridges in the top and bottom sheets encourage polarization of the molecules parallel to the light polarization direction of the sheets. The polarization of the molecules between the sheets twists naturally between the two perpendicular extremes. Light is polarized by one sheet, rotated through the smooth twisting of the crystal molecules, and then passed through the second sheet. Prior to the electric field being applied, the LCD assembly appears nearly transparent. However, once the electric field is applied, the liquid crystal molecules align with the field and inhibit rotation of the polarized light through the structure. Accordingly, the LCD assembly appears dark when the field is applied.

Most high resolution LCD-type FPDs are “active matrix” displays, which in addition to the polarizing sheets and electrically-controlled light-polarizing liquid, contain a two-dimensional matrix of thin-film transistors (TFTs). Each TFT together with a storage capacitor that is electrically coupled to the TFT forms a “pixel” of the display. By controlling the amount of charge stored on the storage capacitors of each of the various pixels, the transmission and blocking function of the liquid crystal can be controlled pixel-by-pixel. thereby allowing the formation of a display capable of displaying two-dimensional images.

Each pixel of an LCD-type FPD maintains its charge state while the storage capacitors of the other pixels are being updated. This allows the display of moving images (e.g., video). To display color, each pixel of the LCD display is divided into three sections, one with a red filter, one with a green filter, and the other with a blue filter. The pixel can be made to appear an arbitrary color by varying the relative brightnesses of its three colored sections.

Multiple FPDs are typically manufactured at the same time by forming a plurality of FPD panels 100 on a single glass substrate 102, as shown in FIG. 1. Forming multiple FPD panels 100 on a single glass substrate 102 not only allows a plurality of FPD panels 100 to be inspected at the same time, it also allows for easier handling.

As described above, active matrix LCD-type FPDs consist of multiple layers, including a two-dimensional matrix of TFTs. The TFT layer is typically the first, or one of the first, layers to be formed on the glass substrate. The TFT layer formed on the glass substrate will be referred to in this disclosure as a “TFT substrate”.

Because nearly all of the defects in LCD-type FPDs originate in the TFT layer, it is this layer that is inspected the most rigorously. A variety of inspection apparatuses have been used and proposed for inspecting TFT substrates. Generally, the various inspection apparatuses can be classified as either “contact-type” or a “non-contact-type” testers. A contact-type tester employs a mechanical probe that makes physical contact with test contacts on the TFT substrate to inspect each of the TFTs for defects. Because each TFT substrate may contain thousands or even millions of pixels, the cumulative time to physically move the probe from contact to the next can be quite long. This is a major drawback associated with contact-type testers.

U.S. Pat. No. 5,982,190 to Toro-Lira discloses a non-contact-type FPD tester that employs electron guns and a voltage waveform contrast technique to inspect TFT substrates. According to this technique, one or more pixels of a TFT substrate are irradiated by one or more electron beams while test signals are applied to the pixels being inspected. In response to the irradiation, the pixels under test emit secondary electrons. These secondary electrons are then collected by an electron detector and converted to an electrical waveform. A signal analyzer compares the resulting electrical waveform to an expected voltage waveform. Because the number of secondary electrons emitted by a defective pixel is substantially different that that emitted from a non-defective pixel, the voltage contrasting technique is useful in determining pixel defects.

FIG. 2A shows a perspective view of an inspection system 20 that uses the voltage waveform contrast technique described by Toro-Lira in U.S. Pat. No. 5,982,190. Top and side views of the system 20 are shown in FIGS. 2B and 2C. The inspection system 20 comprises a load lock chamber 200, a main chamber 202, and a plurality of electron guns 204. The load lock chamber 200 has a front gate valve 206, which can be opened to transfer a TFT substrate into and out of load lock chamber 200. A back gate valve 208 separates the load lock chamber 200 from the main chamber 202. The purpose of the load lock chamber 200 is to allow the transfer of a TFT substrate into and out of the main chamber 202 without having to repeatedly disrupt and reestablish the high-vacuum condition maintained in the main chamber 202. Although not shown in the FIG. 2A, the inspection system 20 also typically includes a prober exchange load lock, which allows different probers to be loaded into and out of the main chamber 202 for inspecting different types of TFT substrates.

To load a TFT substrate into the inspection system 20, the back gate valve 208 is closed and then the front gate valve 206 is slowly opened to vent the load lock chamber 200. Once properly vented, a fab robot places the TFT substrate on a holding slot within the load lock chamber 200 and the front gate valve 206 is closed. Because the back gate valve 208 is also closed the interior of the load lock chamber 200 at this stage in the process is isolated from both the ambient atmosphere and the high-vacuum condition created in the main inspection chamber 202 by one or more turbomolecular pumps 210. The ambient air in the load lock chamber 200 is pumped out by a turbo pump 213 and replaced with an inert gas, such as nitrogen, from an inert gas source (not shown in drawings). As the inert gas displaces the ambient air during pumping, the pressure of the load lock chamber 200 is regulated so that it forced to match the pressure of the high-vacuum condition of the main chamber 202, which is also maintained with an inert gas such as nitrogen.

Once the pressure within the load lock chamber 200 matches the pressure within the main chamber 202, pumping of the load lock chamber 200 is halted and the back gate valve 208 is opened. An internal transfer robot 212 then lifts the TFT substrate from the holding slot of the load lock chamber 200 and transfers the TFT substrate to the inspection stage 214 of the main chamber 202. A prober transfer mechanism is then employed to properly position and align a preselected prober (not shown) over the TFT substrate. The prober is configured to receive test signals from a signal generator and apply those test signals, via probes of the prober, to electrical test contacts of the TFT substrate.

Once the TFT substrate is properly positioned on the inspection stage 214 of the main chamber 202, and the prober is properly aligned to the test contacts of the TFT substrate 304, the TFT substrate 304 is inspected using the voltage waveform contrast technique of Toro-. Lira, which is illustrated in FIG. 3 and explained below. Referring to FIG. 3, one or more electron guns 204 generate an electron beam 300 which irradiates a pixel under test 302 of the TFT substrate 304. A signal generator/analyzer 306 provides test signals, via signal lines 308, to the pixel under test 302. Although not shown in FIG. 3, the test signals are routed to a prober which applies the test signals to the appropriate electrical contacts on the TFT substrate 304. A secondary electron detector 310 collects secondary electrons 312 emitted by the pixel under test 302 and generates an electrical signal based on the number of secondary electrons collected. The signal generator/analyzer 306 analyzes the electrical signal to determine whether the pixel under test 302 is defective.

So that all pixels of the TFT substrate 304 are inspected, the test stage 214 holding the TFT substrate is systematically moved lengthwise through the main chamber 202 as inspection is conducted. (See FIG. 2.) A stepped repositioning of the TFT substrate in a direction perpendicular to the length of the main chamber 202, followed by subsequent passes through the electron beams 300, may be necessary in order to inspect all of the pixels of the TFT substrate. The number of passes that are necessary depends, among other factors, on the number of electron guns 204 employed and the spacing between electron guns 204.

The number of secondary electrons 312 emitted from each pixel 302 of the TFT substrate 304 depends on the polarity of the voltage of the pixel 302 of the TFT substrate 304. When, for example, a pixel 302 in the TFT substrate 304 is driven positively, secondary electrons 312 emitted the pixel 302 are attracted to the pixel 302 because the secondary electrons 307 are negatively charged. Consequently, the number of secondary electrons 312 reaching the secondary electron detector 310 is diminished when the pixel 302 is driven positively. On the other hand, when a pixel 302 in the TFT substrate 304 is driven negatively, secondary electrons 312 emitted by the pixel 302 are repelled by the pixel 302. As a result, the number of secondary electrons 312 reaching the secondary electron detector 310 is enhanced. Because the number of secondary electrons detected depends on how the pixel 302 responds to a signal of a known polarity, measuring the number of secondary electrons emitted can be used to indirectly detect pixel performance, including defects.

Inspection system 20, when combined with the voltage waveform contrast technique of Toro-Lira, provides an effective inspection system for FPDs. Even so, the time necessary to completely inspect an entire TFT substrate can be long. To reduce inspection time a second load lock chamber 404 can be employed, as shown in FIG. 4. Rather than using a single load lock to transfer TFT substrates into and out of the main chamber 402, a first load lock chamber 400 is used solely to transfer TFT substrates into the main chamber 402, and a second load lock chamber 404 is used to remove TFT substrates from the main chamber. Because the first load lock chamber 400 is not needed to remove TFT substrates from the main chamber 402, a to-be-inspected second TFT substrate can be loaded into the first load lock chamber 400, and the first load lock chamber 400 can be pumped while the first TFT substrate in the main chamber 402 is being inspected. Once inspection of the first TFT substrate has completed, and the first TFT substrate is transferred into the second load lock 404, the second load lock 404 can be vented. During this time the second TFT substrate in the pumped first load lock chamber 400 is transferred into the main chamber for inspection.

Use of dual load locks to allow multiple TFT substrates to be inspected one right after the other, as described in the previous paragraph, is referred to in the art as “pipelining”. Pipelining increases throughput, compared to single load lock systems, by eliminating the vent and pump time gaps between inspection of consecutive TFT substrates. Unfortunately, this increased throughput is at the expense of an enlarged tester footprint. The enlarged tester footprint can be problematic, especially when available floor space is limited. The problem is exacerbated as fabrication capabilities allow the manufacture of TFT substrates of ever larger sizes. Just a few years ago, a typical TFT substrate had dimensions of 680×880 mm, which as shown in FIG. 5 requires a dual load lock tester having a footprint over four times as large (i.e., greater than 4×680×880 mm). Today's substrates are substantially larger, having dimensions of up to 2200×2800 mm. The footprint of a dual load lock tester capable of inspecting such large substrates would be greater than 5×6 m, which in most circumstance is prohibitively large.

Due to the ever increasing TFT substrate sizes, simple geometrical scaling of a tester to accommodate the substrates is in most circumstance not an acceptable solution. What is need, therefore, is an inspection system that accommodates large substrates but does not have an overly large footprint.

### SUMMARY OF THE INVENTION

According to an embodiment of the present invention, a plurality of TFT substrate testers share a common rough pump, and perform inspection of TFT substrates at overlapping periods of time. Unlike prior art TFT substrate testers, the testers of the present invention neither have nor require a load lock chamber to load and unload TFT substrates into a main inspection chamber. By sharing a rough pump and not requiring load lock chambers, the footprint of the inspection systems of the present invention are substantially smaller than the footprints of prior art TFT substrate inspection systems. Further, according to another aspect of the invention, one of the testers of the plurality of testers can be loaded or unloaded and pumped and isolated during the same time one or more of the previously-pumped testers are inspecting their TFT substrates. This pipelining operation substantially improves the throughput of the inspection system.

According to another embodiment of the invention, an inspection chamber for a TFT substrate tester employs a plurality of electron guns, the plurality of electron guns arranged in a plurality of rows. By using the plurality of rows of electron guns, a TFT substrate can be inspected in a smaller volume inspection chamber than possible in prior art inspection systems. The smaller volume inspection chamber allows a tester to be built that has a much smaller footprint than which is required for prior art testers.

The rough pump-sharing and multiple-row-electron-gun aspects of the invention may be individually applied, or they may be combined to provide a tester having a substantially smaller footprint than that which is required to inspect similarly-sized TFT substrates using prior art inspection systems.

Further aspects of the invention are described and claimed below, and a further understanding of the nature and advantages of the inventions may be realized by reference to the remaining portions of the specification and the attached drawings.

### BRIEF DESCRIPTION OF THE DRAWINGS

FIG. 1 is a diagram illustrating how a glass substrate typically includes a plurality of flat panel displays (FPDs).

FIG. 2A is a perspective view drawing of a single-load-lock tester, which uses the voltage waveform contrast technique to inspect TFT substrates.

FIG. 2B is a top view drawing of the single-load-lock tester shown in FIG. 2A.

FIG. 2C is a side view drawing of the single-load-lock tester shown in FIGS. 2A and 2B.

FIG. 3 is a conceptual, perspective drawing illustrating the voltage waveform contrast technique.

FIG. 4 is a perspective drawing of a dual-load-lock tester, which uses the voltage waveform contrast technique to inspect TFT substrates.

FIG. 5 is a conceptual diagram illustrating the footprint required of both single-load-lock and dual-load-lock testers to test TFT substrates of increasing sizes.

FIG. 6 is a schematic diagram of an inspection system for inspecting TFT substrates or other types of substrates, according to an embodiment of the present invention.

FIG. 7 is a timing diagram illustrating a method of inspecting TFT substrates using an inspection system similar to that shown in FIG. 6, according to an embodiment of the present invention.

FIG. 8A is a top, cross-sectional diagram of a prior art inspection chamber, illustrating that the required length of the inspection chamber is greater than two times the length of the substrate being inspected.

FIG. 8B shows a top, cross-sectional diagram of the prior art inspection chamber shown in FIG. 8A, where a substrate has been partially inspected after a single lengthwise pass of the substrate beneath a single row of electron guns.

FIG. 9A shows a top, cross-sectional diagram of an inspection chamber and an associated plurality of electron gun rows for testing substrates, according to an embodiment of the present invention.

FIG. 9B shows a top, cross-sectional diagram of the inspection chamber shown in FIG. 9A, and of a partially inspected (shaded) substrate following a single lengthwise pass of the substrate beneath the plurality the plurality of rows of electron guns, according to an embodiment of the present invention.

FIG. 9C shows a top, cross-sectional view of the inspection chamber shown in FIGS. 9A and 9B, illustrating that one or more lateral repositionings of the substrate and one or more passes beneath the plurality of rows of electron guns may be necessary to inspect the entire surface of the substrate, in accordance with the present invention.

FIG. 9D shows a top, cross-sectional view of the inspection chamber shown in FIGS. 9A-C, after the entire surface of the substrate has been inspected in accordance with the present invention.

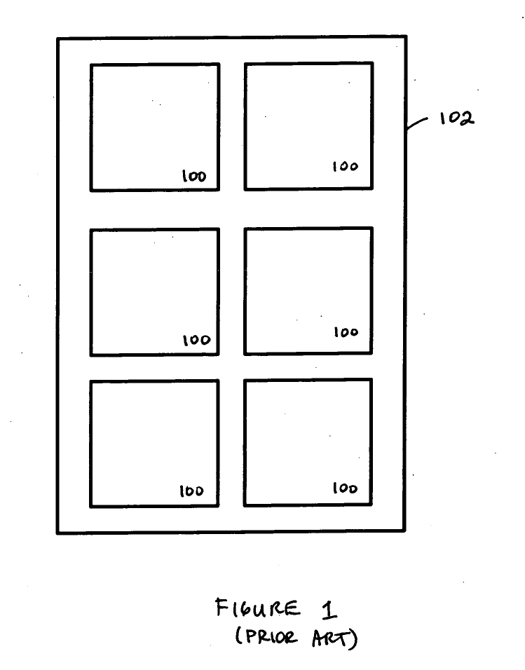

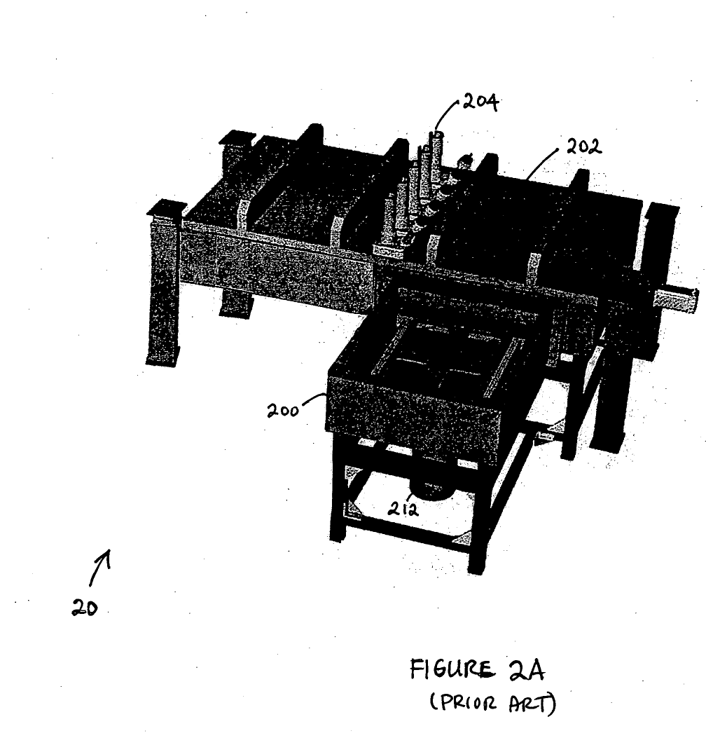

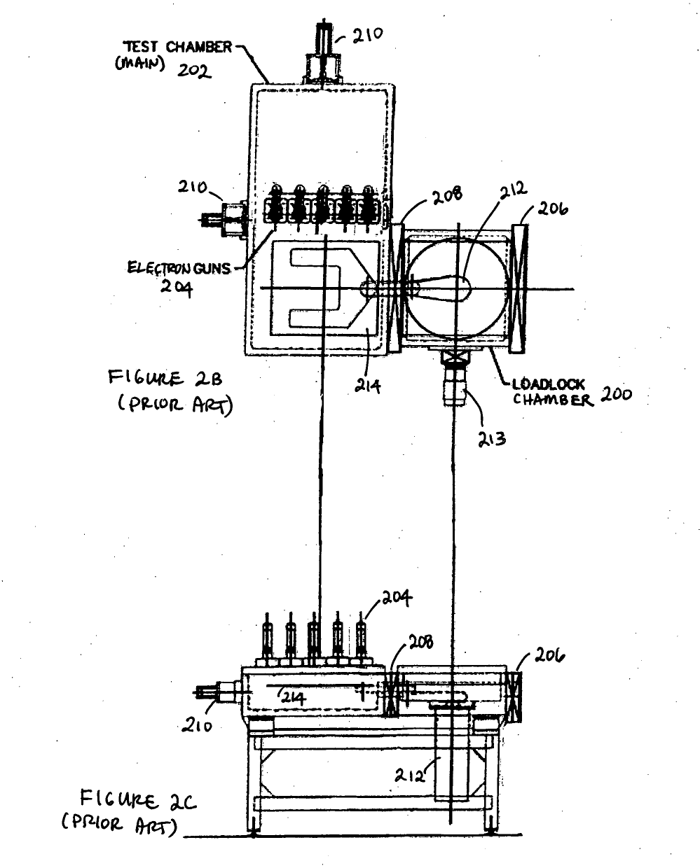

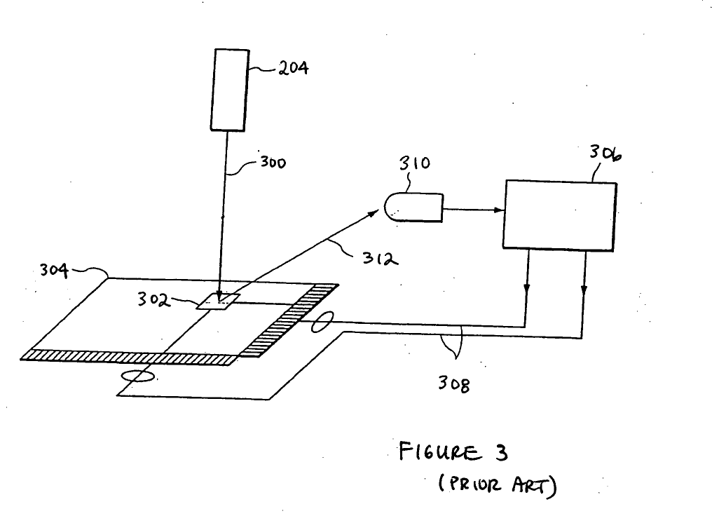

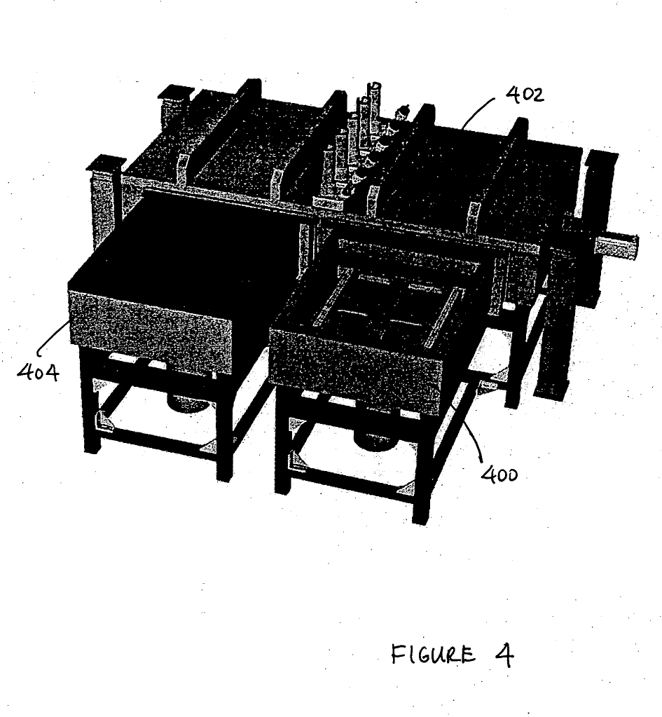

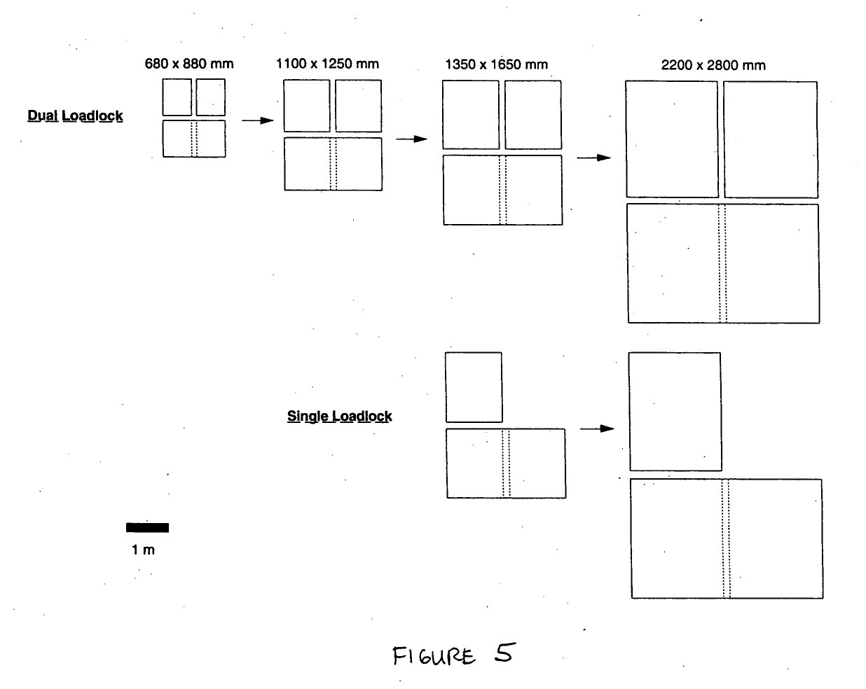

### DETAILED DESCRIPTION

Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. Unless indicated otherwise, the same reference indicators will be used throughout the drawings and the following detailed description to refer to the same or like parts.

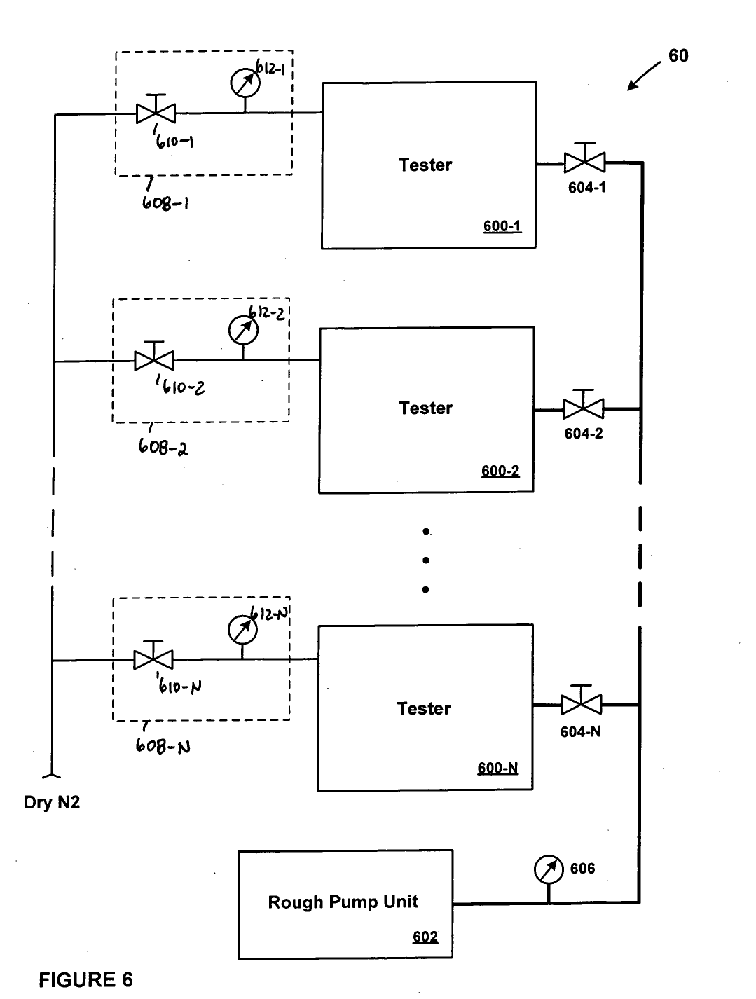

Referring first to FIG. 6, there is shown an inspection system 60 for inspecting TFT substrates or other types of substrates (e.g., semiconductor substrates with or without circuitry partially or completely manufactured therein), according to an embodiment of the present invention. The inspection system 60 is comprised of a plurality of testers 600-1, 600-2, . . . , 600-N, each of the testers 600-1, 600-2, . . . , 600-N including only a single main inspection chamber, i.e., not having a load lock chamber like prior art testers. Within or associated with each of the testers 600-1, 600-2, . . . , 600-N are: an inspection stage for supporting one or more TFT substrates within the inspection chambers; electron guns and a secondary electron detection system configured to perform voltage contrasting; and a prober having electrical contacts for applying test signals to test contacts of the TFTs substrate under inspection.

As shown in FIG. 6 testers 600-1, 600-2, . . . , 600-N share a single rough pump unit 602. The rough pump unit 602 is used to pump out air from the testers 600-1, 600-2, . . . , 600-N and create the high-vacuum conditions needed to properly inspect the TFT substrates. Because only a single rough pump is needed for the plurality of testers 600-1, 600-2, . . . , 600-N, and because the plurality of testers 600-1, 600-2, . . . , 600-N do not require use of load lock chambers, the collective footprint of the inspection system 60 is substantially reduced from that which is needed in prior art inspection systems. Pressure control valves 604-1, 604-2, . . . , 604-N are coupled between the rough pump unit 602 and the chambers of testers 600-1, 600-2, . . . , 600-N. As explained in more detail below, the pressure control valves 604-1, 604-2, . . . , 604-N are controlled so that only one tester is being pumped at any given time. The opening, closing and control of the pressure control valves 604-1, 604-2, . . . , 604-N may be performed manually, mechanically or electrically. The pressure within the tester inspection chambers may be monitored using dedicated pressure gauges at the testers 600-1, 600-2, . . . , 600-N or by using a single pressure gauge 606 at a port of the rough pump unit 602.

Each of the testers 600-1, 600-2, . . . , 600-N also have associated vent control units 608-1, 608-2, . . . , 608-N, which are coupled between ports of the testers 600-1, 600-2, . . . , 600-N and an inert gas source, such as dry nitrogen. The vent control units 608-1, 608-2, . . . , 608-N include vent control valves 610-1, 610-2, . . . , 610-N, which are used to selectively return the pressure within the inspection chambers of the testers 600-1, 600-2 , . . . , 600-N to ambient pressure, following the completion of an inspection of a TFT substrate. Vent control unit pressure gauges 612-1, 612-2, . . . , 612-N are used to monitor the pressure during venting.

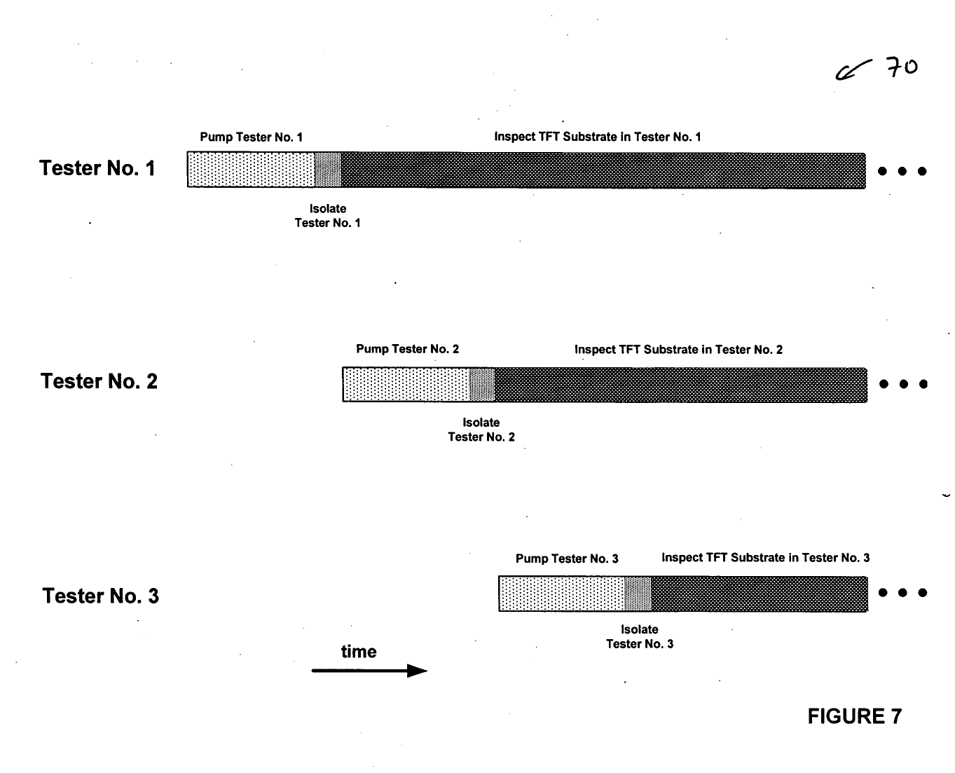

Referring now to FIG. 7, a method 70 of inspecting TFT substrates using the inspection system 60 in FIG. 6 is shown, according to an embodiment of the present invention. In this exemplary embodiment three testers are configured as in FIG. 7. In the discussion that follows, it will be assumed for ease of illustration that the TFT substrates to be inspected have previously been loaded onto the inspection stages of the three testers, and the electronic probers have been properly positioned and aligned to the TFT substrate in preparation for voltage waveform contrasting inspection. In practice, however, while one TFT substrate is being inspected in a particular tester, other TFT substrates are loaded and/or unloaded into and out of the inspection chamber(s) of the other tester(s). Proper unloading requires that the inspection chamber be vented to atmospheric pressure, as explained above.

During a first step in the method 70, the pressure control valve 604-1 between Tester No. 1 and the rough pump unit 602 is opened and the pressure control valves 604-2 and 604-3 between the rough pump unit 602 and Tester Nos. 2 and 3 are closed. The rough pump unit 602 pumps (i.e., removes) air from the chamber of Tester No. 1. Pumping continues until the pressure gauge 606 indicates that the high-vacuum condition created is suitable for inspecting the TFT substrate positioned in Tester No. 1.

After the appropriate inspection pressure is obtained, the pressure control valve 604-1 of Tester No. 1 is closed so that the inspection chamber of Tester No. 1 is isolated. Once the isolation step has completed, inspection of the TFT substrate in Tester No. 1 commences. Inspection is preferably of the voltage waveform contrast technique described (or similar to that described) in U.S. Pat. No. 5,982,190 and U.S. Patent Application No. 2004/0174182, both of which are incorporated into this disclosure by reference.

At some time while the TFT substrate in Tester No. 1 is being inspected, the pressure control valve 604-2 at Tester No. 2 is opened so that air can be pumped from the inspection chamber of Tester No. 2. Pumping Tester No. 2 while Tester No. 1 inspects eliminates the time wasted in prior art approaches needed to prepare the second tester for inspection. After the appropriate inspection pressure is obtained, the pressure control valve 604-2 of Tester No. 2 is closed so that the inspection chamber of Tester No. 2 is isolated. Once the isolation step has completed, inspection of the TFT substrate in Tester No. 2 commences.

The pipeline inspection operation described above continues while Tester No. 2 and/or Tester No. 1 inspect their respective TFT substrates. The pressure control valve 604-3 at Tester No. 3 is opened so that air can be pumped from the inspection chamber of Tester No. 3. Pumping Tester No. 3 while Tester No. 2 and/or 1 are inspecting eliminates the time wasted in prior art approaches needed to prepare the third tester for inspection. After the appropriate inspection pressure is obtained, the pressure control valve 604-3 of Tester No. 3 is closed so that the inspection chamber of Tester No. 3 is isolated. Once the isolation step has completed, inspection of the TFT substrate in Tester No. 3 commences.

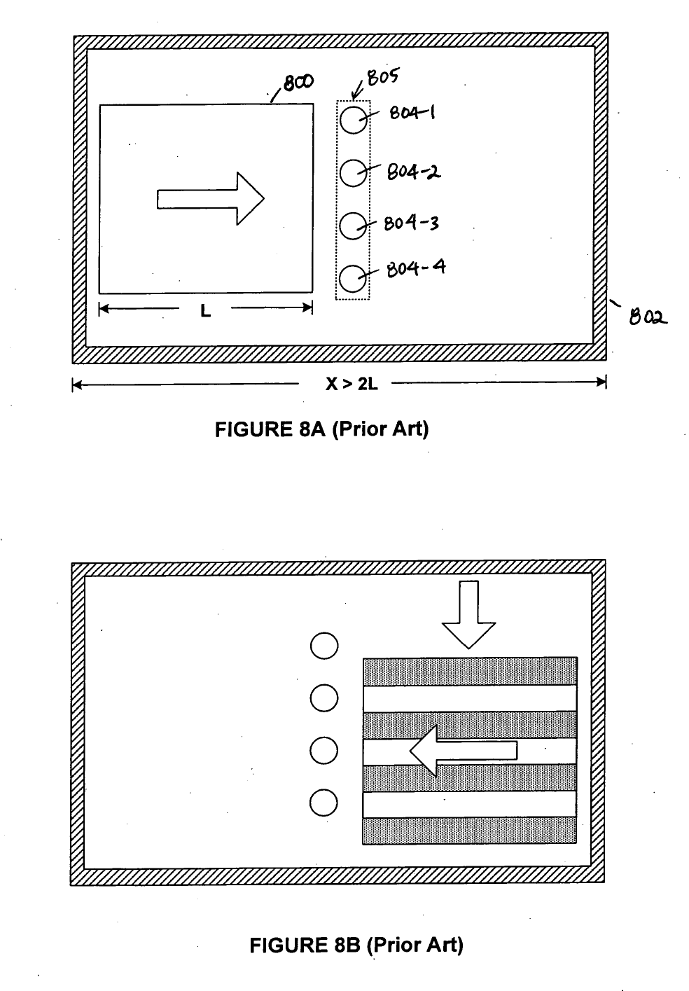

As explained above, and as shown schematically in FIGS. 8A through 8C, in the prior art a TFT substrate 800 is typically positioned on an inspection stage within the inspection chamber 802. The inspection stage is then moved, e.g., by a robotic arm, under a plurality of stationary electron guns 804-1, 804-1, 804-3, 804-4, which are arranged in a single row 805, while test signals are applied to the various TFTs via a prober frame. The prober frame has probe contacts that are electrically and selectively coupled to a test signal generator. The prober frame also moves with the inspection stage and TFT substrate 800 while the TFT substrate is being inspected. More than one lengthwise pass (two needed in the example shown in FIGS. 8A-C) of the TFT substrate 800 beneath the electron guns 804-1, 804-1, 804-3, 804-4 is required in order to complete the inspection of the entire TFT substrate 800. The number of passes necessary, depends on the spacing between electron guns, the surface area coverage of the electron beams, and the capabilities of the secondary electron detector.

As can be seen in FIG. 8A, because at least one full pass of a TFT substrate beneath the electron guns 804-1, 804-1, 804-3, 804-4 is required to inspect a TFT substrate 800 in a prior art system like that shown in FIGS. 8A-8C, the length X of the inspection chamber 802 is required to be at least two times greater than the length, L, of the TFT substrate 800. The lengths of today's TFT substrates are nearly 3 meters. This means that the required size of the inspection chamber 802 (i.e., X>2 L) is quite large. A large inspection chamber is undesirable since it not only results in a tester having a large footprint, it also makes the management and maintenance of the high vacuum condition needed in the inspection chamber difficult, costly and time consuming.

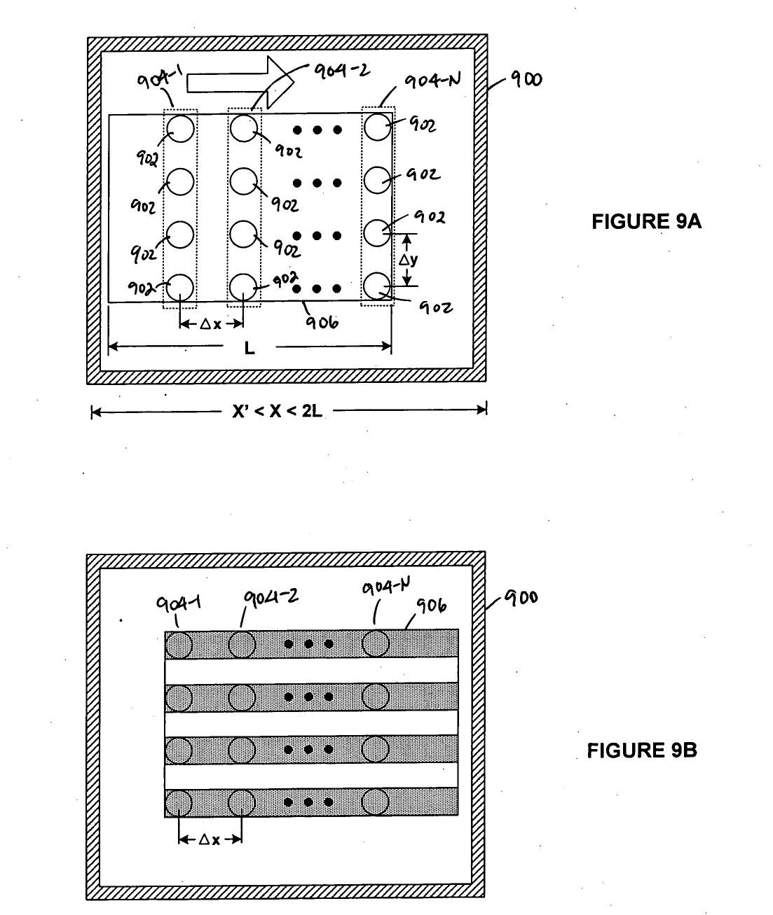

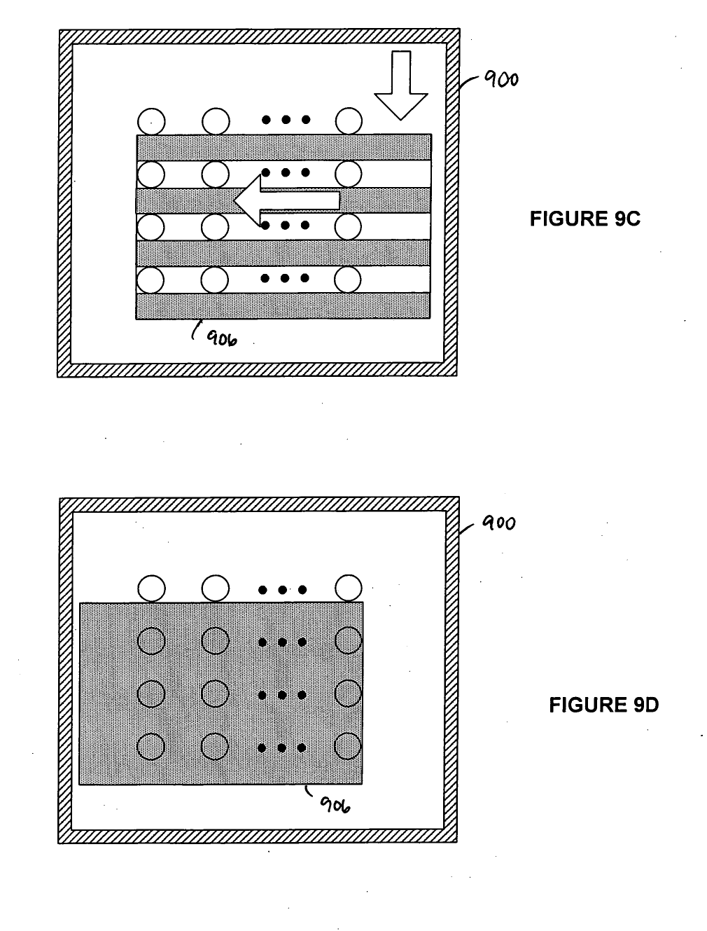

Referring now to FIGS. 9A-9D, there is shown a top cross-sectional view of an inspection chamber 900 for a TFT substrate tester, according to an embodiment of the present invention. A plurality of electron guns 902 are arranged in a plurality of electron gun rows 904-1, 904-2, . . . , 904-N. Adjacent electron guns 902 in a given row are separated by a distance Δy. The electron gun rows are separated by a distance Δx, which may be less than, equal to, or greater than Δy.

TFT substrate 906 is inspected in the inspection chamber 900 by first positioning the TFT substrate 906 on an inspection stage within the inspection chamber 900. Then, a prober frame, which has electrical probes for applying test signals from a signal generator to appropriate test contacts of the TFT substrate 906, is positioned over the TFT substrate 906. During inspection, the inspection stage is moved, e.g., by a robotic arm, under the plurality of stationary electron guns 902. As the inspection stage is moved beneath the electron guns, test signals are applied via the prober frame, to the appropriate test contacts on the TFT substrate 906. At the same time, the electron guns focus electron beams on the TFTs being inspected. The secondary electrons emitted from the various TFTs being inspected are collected by an electron detector and voltage waveform contrasting is used to determine the operational characteristics (e.g. shorted, open, defective, etc.) of the TFTs of the TFT substrate.

FIG. 9B shows inspected (shaded) and yet-to-be-inspected “strips” of the TFT substrate 906. Although the length of the inspected strips have a length equal to the length L of the TFT substrate 906, the substrate itself needed to be moved only a fraction of the of the length L. The reduced distance required is made possible by employing the plurality of electron gun rows 904-1, 904-2, . . . , 904-N. Because the TFT substrate 906 does not need to move as much, the length X′ of the inspection chamber 900 can be made much shorter than the length X required in prior art approaches. Consequently, a smaller footprint tester can be realized compared to that which is possible in prior art inspection systems like that shown and discussed above in connection with FIGS. 8A-8C.

FIG. 9C illustrates how one or more lateral “steps” of the inspection stage in the y-direction (i.e., in the direction perpendicular to the length of the inspection chamber 900) and one or more lengthwise passes may be necessary to inspect the entire TFT substrate 906. FIG. 9D shows the TFT substrate 906 after its entire area has been inspected. In this exemplary embodiment, only two passes of the TFT substrate 906 were needed to inspect the entire surface of the TFT substrate 906.

Although only four electron guns 902 per electron gun row 904-1, 904-2, . . . , 904-N are used in the exemplary embodiment shown in FIGS. 9A-D, those of ordinary skill in the art will readily appreciate and understand that any number of rows and columns of electron guns may be employed, depending on the application at hand.

According to another embodiment of the present invention, the plurality rows of electron guns 904-1, 904-2, . . . , 904-N discussed and illustrated in relation to FIGS. 9A-D may be employed in the inspection chambers of one or more of the testers, 600-1, 600-2, . . . , 600-N of the inspection system 60 shown in FIG. 6. In this manner, the sharing of the rough pump unit 602 and the use of a plurality electron gun rows in the inspection chambers of the testers 600-1, 600-2, . . . , 600-N are combined to reduce the overall footprint of the inspection system.

The foregoing detailed description is intended to illustrate and not limit the scope of the invention, which is defined by the scope of the appended claims. Other aspects, advantages, and modifications are within the scope of the following claims.

What is claimed is:

1. A substrate inspection system, comprising:
a plurality of load-lock-less inspection chambers;
a pump unit; and
a plurality of valves configured to selectively couple the pump unit to a selected one of the plurality of inspection chambers,
wherein the pump unit is configured to pump air out of the selected one of the plurality of inspection chambers while a substrate or substrates in one or more of the remaining plurality of load-lock-less inspection chambers is being inspected.

2. The substrate inspection system according to claim 1 wherein each load-lock-less inspection chamber has a plurality of rows of electron guns, said plurality of rows of electron guns operable to provide an electron source for performing voltage waveform contrasting.

3. The substrate inspection system according to claim 1 wherein each of the plurality of load-lock-less inspection chambers has an interior length that is less than two times the length of the substrates being inspected.

4. An inspection system for inspecting thin-film transistor (TFT) substrates, comprising:
a plurality of inspection chambers, each inspection chamber having an inspection stage configured to support and reposition a TFT substrate within the inspection chamber;
a pump unit selectively coupled to said plurality of inspection chambers; and
a plurality of valves configured to selectively couple the pump unit to one of the plurality of inspection chambers,
wherein one or more TFT substrates in respective one or more of the plurality of inspection chambers can be inspected while another TFT substrate is being removed from or placed on the test stage of another inspection chamber.

5. The inspection system of claim 4 wherein no load locks are required to load or unload TFT substrates into or out of the plurality of inspection chambers.

6. The inspection system of claim 4 wherein each inspection chamber has a plurality of rows of electron guns, said plurality of rows of electron guns operable to provide an electron source that impinges on TFTs of the TFT substrates when test signals are applied to the TFTs.

7. The inspection system of claim 6 wherein secondary electrons emitted by the TFTs are collected by an electron detector and used to generate electrical waveforms.

8. The inspection system of claim 7 wherein the electrical waveforms, when compared to expected waveforms, provide information concerning whether or not the TFTs are defective.

9. The inspection system of claim 4 wherein each of the plurality of inspection chambers has an interior length that is less than two times the length of the substrates being inspected.

10. A method of inspecting thin-film transistor (TFT) substrates, comprising:
loading a first TFT substrate into a first load-lock-less inspection chamber;
pumping air out of the first load-lock-less inspection chamber using a pump;
inspecting the first TFT substrate;
loading a second TFT substrate into a second load-lock-less inspection chamber while the first TFT substrate is being inspected.

11. The method of claim 10 wherein the second TFT substrate is loaded into the second load-lock-less inspection chamber during at least a portion of the time the first TFT substrate is being inspected.

12. The method of claim 10, further comprising pumping air out of the second load-lock-less inspection chamber using the same pump used to pump air out of the first load-lock-less inspection chamber.

13. The method of claim 12 wherein pumping air out of the second load-lock-less inspection chamber is performed during at least a portion of the time the first TFT substrate is being inspected.

14. The method of claim 13, further comprising inspecting the second TFT substrate.

15. The method of claim 14 wherein inspecting the second TFT substrate is performed at least during a portion of the time the first TFT substrate is being inspected.

16. The method of claim 10, further comprising directing a plurality of electron beams onto TFTs of the first TFT substrate while the first TFT substrate is being inspected.

17. The method of claim 16 wherein the plurality of electron beams originate from a plurality of electron guns arranged in a plurality of rows.

18 The method of claim 17, further comprising:
collecting secondary electrons emitted by TFTs of the first TFT substrate; and
generating electrical waveforms from the collected secondary electrons.

19. The method of claim 18, further comprising comparing the electrical waveforms to expected waveforms.

20. The method of claim 19 wherein comparing the electrical waveforms to the expected waveforms provides information concerning whether or not the TFTs are defective.

21. The method of claim 10 wherein the first load-lock-less inspection chambers has an interior length that is less than two times the length of the first TFT substrate.
